(19) United States
(12) Patent Application Publication
(10) Pub. No.: US 2025/0112157 A1
(43) Pub. Date: Apr. 3, 2025

(54) SYSTEM AND METHODS FOR A METAL INTERFACE ARCHITECTURE

(71) Applicant: Samsung Electronics Co., Ltd., Suwon-si (KR)

(72) Inventors: Jin YANG, San Jose, CA (US); WooPoung KIM, San Jose, CA (US)

(21) Appl. No.: 18/655,217

(22) Filed: May 3, 2024

Related U.S. Application Data
(60) Provisional application No. 63/541,776, filed on Sep. 29, 2023.

(51) Int. Cl. H01L 23/532; H01L 21/768

(52) U.S. Cl. CPC H01L 23/53238; H01L 21/76823; H01L 21/7684

(57) ABSTRACT

A method, system, and devices are disclosed herein involving a first substrate with a first grain layer, a second substrate with a second grain layer, and a third grain layer contacting the first grain layer and the second grain layer. The third grain layer having an average grain size smaller than the first grain layer and second grain layer.

### CROSS-REFERENCE TO RELATED APPLICATION

This application claims the priority benefit under 35 U.S.C. § 119(e) of U.S. Provisional Patent Application Ser. No. 63/541,776 filed on Sep. 29, 2023, the disclosure of which is incorporated herein by reference in its entirety.

### TECHNICAL FIELD

The subject matter disclosed herein relates to packaging. More particularly, the subject matter disclosed herein relates to a technique for bonding devices between substrates.

### BACKGROUND

Semiconductor devices may connect to additional devices and circuitry on different substrates. Conductors such as metal may be used to form connections on substrates, such as in the form of traces. However, forming connections between substrates can cause difficulties. It is further noted that background concepts discussed herein are for informational purposes only and are not intended to limit the present disclosure.

### SUMMARY

An example embodiment provides a device including a first substrate, the first substrate including a first conductive region and a first insulative region, the device including a second substrate, the second substrate including a second conductive region contacting the first conductive region, and a second insulative region contacting the first insulative region. In some embodiments, the first conductive region has a first grain layer and a second grain layer contacting the first grain layer, the second grain layer having a larger average grain size than the first grain layer. In some embodiments, the second conductive region has a third grain layer and a fourth grain layer contacting the third grain layer, the fourth grain layer having a larger average grain size than the third grain layer. In some embodiments, at least one of the first grain layer and third grain layer has a thickness of a single-grain layer.

In some embodiments, a crystalline orientation of the first grain layer and the second grain layer may differ and a crystalline orientation of the third grain layer and the fourth grain layer may differ. In some embodiments, a crystalline orientation of the first grain layer and the second grain layer may be substantially the same and a crystalline orientation of the third grain layer and the fourth grain layer may be substantially the same. In some embodiments, a crystalline orientation of the first grain layer and the third grain layer may be substantially the same and a crystalline orientation of the second grain layer and the fourth grain layer may differ. In some embodiments, the first grain layer and the third grain layer may have substantially the same average grain size. In some embodiments, the first grain layer may include a first copper layer and the second grain layer may include a second copper layer different from the first copper layer. In some embodiments, the third grain layer may include a third copper layer and the fourth grain layer may include a fourth copper layer different from the third copper layer. In some embodiments, the second copper layer differs from the fourth copper layer. In some embodiments, at least one of the first grain layer and the third grain layer may form an electromigration barrier between the second grain layer and the fourth grain layer. In some embodiments, the average grain size of at least one of the first grain layer and the third grain layer may be less than about 10 nanometers; and the average grain size of each of the second grain layer and the fourth grain layer may be greater than about 0.1 micron.

In some embodiments, a device includes a first grain layer contacting a first substrate, a second grain layer contacting a second substrate, and a third grain layer contacting the first grain layer and the second grain layer, the third grain layer having an average grain size smaller than the first grain layer and the second grain layer. In some embodiments, a crystalline orientation of the first grain layer, the second grain layer, and the third grain layer may be substantially the same. In some embodiments, a crystalline orientation of the first grain layer and the second grain layer may differ and a crystalline orientation of the third grain layer may differ from both the first grain layer and the second grain layer. In some embodiments, a crystalline orientation of the first grain layer and the second grain layer may differ and a crystalline orientation of the third grain layer differs from at least one of the first grain layer and the second grain layer. In some embodiments, the average grain size of the third grain layer may be less than about 10 nanometers. In some embodiments, the average grain size of at least one of the first grain layer and the second grain layer may be greater than about 0.1 micron.

In some embodiments, a method includes depositing a first insulative region on a first substrate, forming a first recess in the first insulative region, and depositing a first conductive layer in the first recess. A second insulative region may be deposited on a second substrate, forming a second recess in the second insulative region, and depositing a second conductive layer in the second recess. A third conductive layer may be formed on the first conductive layer and forming a fourth conductive layer on the second conductive layer, at least one of the third conductive layer and the fourth conductive layer having a different grain orientation than the first conductive layer and the second conductive layer. The first insulative region may be bonded to the second insulative region. The first substrate and the second substrate may be annealed at a temperature of less than 250° C. to bond the third conductive layer and the fourth conductive layer into a single layer.

In some embodiments, the first conductive layer and the second conductive layer may be formed using electro-chemical deposition plating; and the third conductive layer and the fourth conductive layer may be formed using at least one of physical layer deposition and atomic layer deposition. In some embodiments, annealing the first substrate and the second substrate may be done at a temperature of less than 200° C. In some embodiments, the first conductive layer may be polished to expose a surface of the first insulative region prior to forming the third conductive layer. In some embodiments, the second conductive layer may be polished to expose a surface of the second insulative region prior to forming the fourth conductive layer. In some embodiments, the third conductive layer may be polished to expose the surface of the first insulative region and the fourth conductive layer may be polished to expose the surface of the second insulative region prior to bonding the first insulative region to the second insulative region. In some embodiments, the first conductive layer and the third conductive layer may be polished together to expose a surface of the first insulative region, and the second conductive layer and the fourth conductive layer may be polished together to expose a surface of the second insulative region. In some embodiments, forming the first recess in the first insulative region and forming the second recess in the second insulative region may be done using photolithography, and the third conductive layer and the fourth conductive layer may be unpatterned when bonded.

### BRIEF DESCRIPTION OF THE DRAWING

In the following section, the aspects of the subject matter disclosed herein will be described with reference to exemplary embodiments illustrated in the figures, in which:

FIG. 1 depicts a cross-section view of an example embodiment of a packaging structure according to various embodiments of the subject matter disclosed herein;

FIG. 2 depicts a cross-section view of an example embodiment of a packaging structure according to various embodiments of the subject matter disclosed herein;

FIG. 3A depicts a cross-section view of an example embodiment of an assembly of a packaging structure in a first position, according to various embodiments of the subject matter disclosed herein;

FIG. 3B depicts a cross-section view of an example embodiment of an assembly of a packaging structure in a second position, according to various embodiments of the subject matter disclosed herein;

FIG. 3C depicts a cross-section view of an example embodiment of an assembly of a packaging structure in a third position, according to various embodiments of the subject matter disclosed herein;

FIG. 4A depicts a cross-section view of an example embodiment of an assembly of a packaging structure in a first position, according to various embodiments of the subject matter disclosed herein;

FIG. 4B depicts a cross-section view of an example embodiment of an assembly of a packaging structure in a second position, according to various embodiments of the subject matter disclosed herein;

FIG. 4C depicts a cross-section view of an example embodiment of an assembly of a packaging structure in a third position, according to various embodiments of the subject matter disclosed herein;

FIG. 5A depicts a cross-section view of an example embodiment of configuring a packaging structure in a first position, according to various embodiments of the subject matter disclosed herein;

FIG. 5B depicts a cross-section view of an example embodiment of an assembly of a packaging structure in a second position, according to various embodiments of the subject matter disclosed herein;

FIG. 5C depicts a cross-section view of an example embodiment of an assembly of a packaging structure in a third position, according to various embodiments of the subject matter disclosed herein;

FIG. 5D depicts a cross-section view of an example embodiment of an assembly of a packaging structure in a fourth position, according to various embodiments of the subject matter disclosed herein;

FIG. 5E depicts a cross-section view of an example embodiment of an assembly of a packaging structure in a fifth position, according to various embodiments of the subject matter disclosed herein;

FIG. 5F depicts a cross-section view of an example embodiment of an assembly of a packaging structure in a sixth position, according to various embodiments of the subject matter disclosed herein;

FIG. 5G depicts a cross-section view of an example embodiment of an assembly of a packaging structure in a seventh position, according to various embodiments of the subject matter disclosed herein;

FIG. 5H depicts a cross-section view of an example embodiment of an assembly of a packaging structure in an eighth position, according to various embodiments of the subject matter disclosed herein;

FIG. 5I depicts a cross-section view of an example embodiment of an assembly of a packaging structure in a ninth position, according to various embodiments of the subject matter disclosed herein;

FIG. 5J depicts a cross-section view of an example embodiment of an assembly of a packaging structure in a tenth position, according to various embodiments of the subject matter disclosed herein;

FIG. 5K depicts a cross-section view of an example embodiment of an assembly of a packaging structure in an eleventh position, according to various embodiments of the subject matter disclosed herein;

FIG. 6 depicts an example embodiment of a method of preparing a substrate for packaging according to various embodiments of the subject matter disclosed herein;

FIG. 7 depicts an example embodiment of a method of bonding two substrates according to various embodiments of the subject matter disclosed herein; and

FIG. 8 depicts an example embodiment of a method of packaging two substrates according to various embodiments of the subject matter disclosed herein.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “pre-determined,” etc.) may be occasionally interchangeably used with a corresponding non-hyphenated version (e.g., “two dimensional,” “predetermined, etc.), and a capitalized entry (e.g., “Counter Clock,” “Row Select,” “PIXOUT,” etc.) may be interchangeably used with a corresponding non-capitalized version (e.g., “counter clock,” “row select,” “pixout,” etc.). Such occasional interchangeable uses shall not be considered inconsistent with each other.

Also, depending on the context of discussion herein, a singular term may include the corresponding plural forms and a plural term may include the corresponding singular form. It is further noted that various figures (including component diagrams) shown and discussed herein are for illustrative purpose only, and are not drawn to scale. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein dielectrics may refer to a variety of materials including various forms of silicon such as silicon oxides including SiO₂, silicon nitrides including SiN, silicon carbonitrides including SiCN, Tetraethyl orthosilicate (TEOS), as well as other known materials in the art, alone or in combination. In some embodiments, dielectric materials may be formed from the surface of a substrate. In other embodiments, dielectric materials may be deposited onto a substrate surface. In some embodiments, dielectric materials may be formed via a combination of growth from the substrate and deposition of materials. In some embodiments, dielectric materials may be referred to as electrically insulating materials, insulative regions, or as insulators. In some embodiments, the amount of insulation provided may be relative to another material which may be referred to as a conductive material or conductor.

As used herein substrates may refer to a variety of materials and structures, including wafers using silicon, wafers using silicon on an insulator (SOI) such as glass, wafers of other semiconductor materials such as germanium, as well as other semiconductor materials on an insulator. In some embodiments, a substrate may include an organic material. In some embodiments, the substrates may be referred to as wafers, dies, and chips alone or in combination. Bonding substrates may be thus known in some embodiments as die-to-die (D2D) bonding, wafer-to-wafer bonding (W2W) or die-to-wafer bonding (D2W). In some embodiments, the substrates may contain circuits such as integrated circuits including central processing units (CPUs), logic chips, memory such as static random-access memory (SRAM), dynamic random-access memory (DRAM), application processors (AP), graphical processing units (GPUs), artificial intelligence (AI) chips, High bandwidth memory (HBM) interfaces, and other application-specific integrated circuits (ASIC). In some embodiments, a combination of circuits may be present on a substrate. In some embodiments, a substrate may include a packaged chip.

As used herein packaging refers to a process of forming interconnections between substrates. In some embodiments, the interconnections may be between direct surfaces and involve W2W, D2D, and D2W bonding. In other embodiments, techniques including wire bonding and other forms of indirect bonding may be performed alone or in combination with W2W, D2D, and D2W bonding. In some embodiments, circuits may be bonded directly facing each other, while in other embodiments a flip-chip bonding may be used. In some embodiments, interconnections may be made between substrates on a front or circuit side of the substrate. In other embodiments, interconnections may be made on a rear or back side of the substrate opposite from the circuit structure. In some embodiments, an interconnection may include through-silicon vias (TSVs) or other forms of through-chip vias where one or more substrates may be connected using a via traveling through an interposer such as another substrate or chip. In some embodiments, an interconnection may be formed using connections on a surface of a substrate, such as a pad, and may use additional materials between the pads such as solder to form an interconnection.

As used herein, conductors may refer to a variety of conductive materials, including which materials may be used alone or in combination with other materials such as in the form of an alloy. In some embodiments the conductor is copper (Cu). In some embodiments, copper (Cu) may be in the form of Cu (II), Cu (III) or other forms of copper, alone or in combination with additional elements, including cobalt (Co) and ruthenium (Ru). Such a listing of elements is not intended to be exhaustive, and in other embodiments, any known other type of conductive material may be used.

As used herein, the terms “single-grain layer” and “monolayer” may each refer to a layer having an average thickness in a direction perpendicular to a major surface which is a single grain. As used herein, the term “single grain” may refer to a single crystalline structure, as well as a single layer of crystal. For example, a single grain layer with an average grain size of 5 nanometers (nm) would have an average thickness of 5 nm. In some embodiments, a surface interface may exist between a single-grain layer and any surrounding materials.

Disclosed herein are various devices, structures and methods for forming a conductive interface between two or more substrates using multiple layers of a conductive material, such as metal materials. For example, the conductive material may include multiple layers of copper used to form an interconnection between two wafers. The layers of conductive materials may be formed using differing manufacturing techniques to produce different characteristics and properties in an interconnection. For example, some layers may be created using formed using a process such as physical vapor deposition (PVD) or atomic layer deposition (ALD), as well as electro-chemical deposition plating (ECD). In some embodiments, the interconnection may include bonding between conductive materials at a surface of a substrate, as well as bonding between dielectric materials on a surface of a substrate. In some embodiments, the bonding process may use a hybrid bonding process in which both the dielectric and conductive regions are bonded together between substrates.

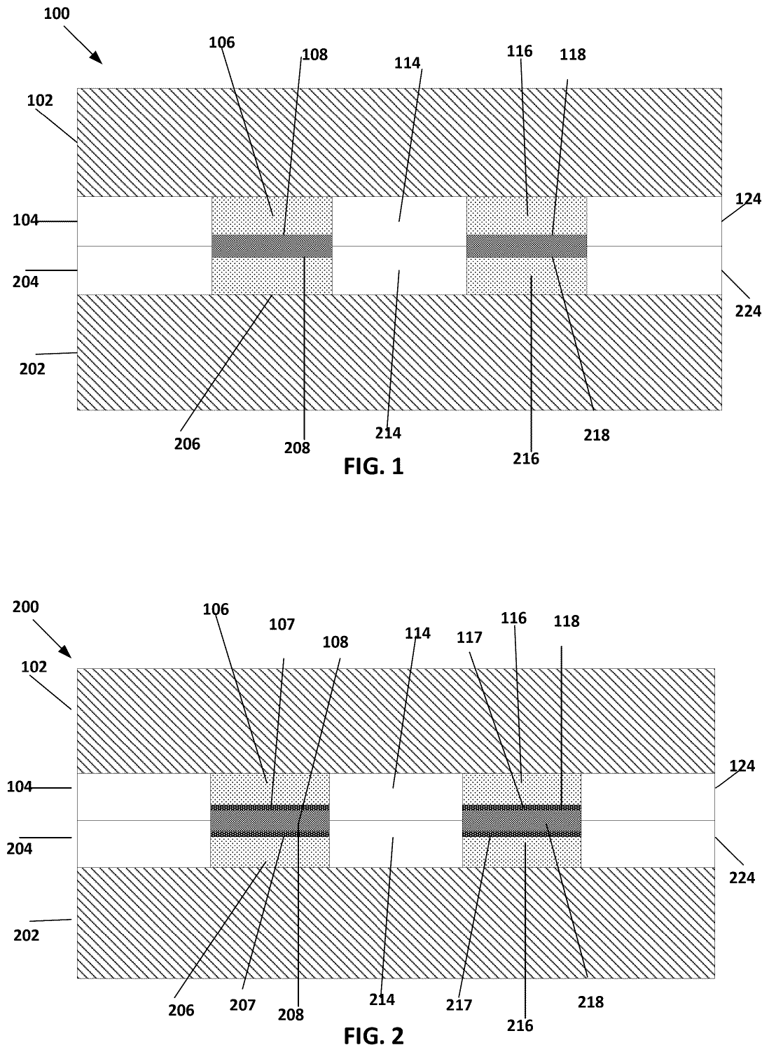

FIG. 1 discloses an exemplary embodiment of a packaging structure 100 including a first substrate 102 and a second substrate 202. The first substrate 102 is shown with a dielectric layer including a first dielectric portion 104, a second dielectric portion 114, and a third dielectric portion 124 in contact with the first substrate 102. In some embodiments, additional layers and structures may be placed between a dielectric layer and the first substrate 102. The first substrate 102 is also shown having a first conductive layer having a first base conductive portion 106 and a second base conductive portion 116 in contact with the first substrate 102. In some embodiments, additional layers and structures may be placed between a conductive layer and the first substrate 102, for example, portions of the dielectric layer may be between the first substrate 102 and one or more of the first base conductive portion 106 and the second base conductive portion 116. Additionally, the first base conductive portion 106 and the second base conductive portion 116 are in contact with a first outer conductive portion 108 and second outer conductive portion 118, respectfully.

Also shown in FIG. 1 is a second substrate 202, the second substrate 202 with a dielectric layer including a fourth dielectric portion 204, a fifth dielectric portion 214, and a sixth dielectric portion 224 in contact with the second substrate 202. In some embodiments, additional layers and structures may be placed between a dielectric layer and the second substrate 202. The second substrate 202 is also shown having a first inner conductive layer having a third base conductive portion 206 and a fourth base conductive portion 216 in contact with the second substrate 202. In some embodiments, additional layers and structures may be placed between a conductive layer and the second substrate 202, for example, portions of the dielectric layer may be between the second substrate 202 and one or more of the third base conductive portion 206 and the fourth base conductive portion 216. Additionally, the third base conductive portion 206 and the fourth base conductive portion 216 are in contact with a third outer conductive portion 208 and a fourth outer conductive portion 218, respectfully.

In the packaging structure 100, the first substrate 102 and the second substrate 202 are bonded with a contact between corresponding dielectric portions and corresponding conductor portions on the substrates. The first dielectric portion 104 is thus bonded to the fourth dielectric portion 204, the second dielectric portion 114 is bonded to the fifth dielectric portion 214, the third dielectric portion 124 is bonded to the sixth dielectric portion 224. The first outer conductive portion 108 is thus bonded to the third outer conductive portion 208 and the second outer conductive portion 118 is bonded to the fourth outer conductive portion 218. As shown in FIG. 1, the first base conductive portion 106, the second base conductive portion 116, the third base conductive portion 206, and the fourth base conductive portion 216 are not in direct contact with each other, but instead are between the substrates and an additional conductive layer.

The first base conductive portion 106, the second base conductive portion 116, the third base conductive portion 206, and the fourth base conductive portion 216 may be formed using a bulk process such as electro-chemical deposition plating to create large grain structures. In some embodiments, the large grain structures may have an average grain size in the range of 0.5 microns to 5 microns. Furthermore, the thickness of the large grain structures may be in the range of 0.5 microns to 5 microns. In some embodiments, the large grain structures may be further decreased in size based on improvements to the manufacturing capabilities.

In contrast, the first outer conductive portion 108, the second outer conductive portion 118, the third outer conductive portion 208, and the fourth outer conductive portion 218 may be formed using a process such as PVD or ALD, allowing a smaller grain structure than those of the large grain structures. For example, the small grain structures may be 2-5 nm in average grain size using ALD, or 5-10 nm in average grain size using PVD. Additionally, the small grain structures may have a thickness of between 2-10 nm. In some embodiments, the large grain structures may be further decreased in size based on improvements to the manufacturing capabilities.

Furthermore, the opposing portions of small grain structures of the first outer conductive portion 108 and the third outer conductive portion 208, as well as the second outer conductive portion 118 and the fourth outer conductive portion 218, may form a monolayer of a single grain thickness.

Additionally, while FIG. 1 shows three dielectric portions and two conductive portions on each substrate, in other embodiments, the number of dielectric portions and conductive portions may be increased as necessary. Furthermore, a dish size defining the recess with the conductive portions may vary, for example between 1-10 nm, with the dish size in some embodiments equaling the size of a pitch between conductive portions.

FIG. 2 provides an exemplary embodiment of a second packaging structure 200. FIG. 2, differing from FIG. 1 by including an intermediate conductive layer between the large grain structure layer and the small grain structure layer, with a first intermediate conductive portion 107 between the first base conductive portion 106 and the first outer conductive portion 108, a second intermediate conductive portion 117 between the second base conductive portion 116 and the second outer conductive portion 118, a third intermediate conductive portion 207 between the third base conductive portion 206 and the third outer conductive portion 208, and a fourth intermediate conductive portion 217 between the fourth base conductive portion 216 and fourth outer conductive portion 218. In some embodiments, the intermediate conductive layer may be used to mitigate electromigration between the inner layers and outer layers, forming an electromigration barrier. In some embodiments, the intermediate conductive layer may be formed using a process such as PVD or ALD. In some embodiments, the intermediate conductive layer may comprise multiple layers.

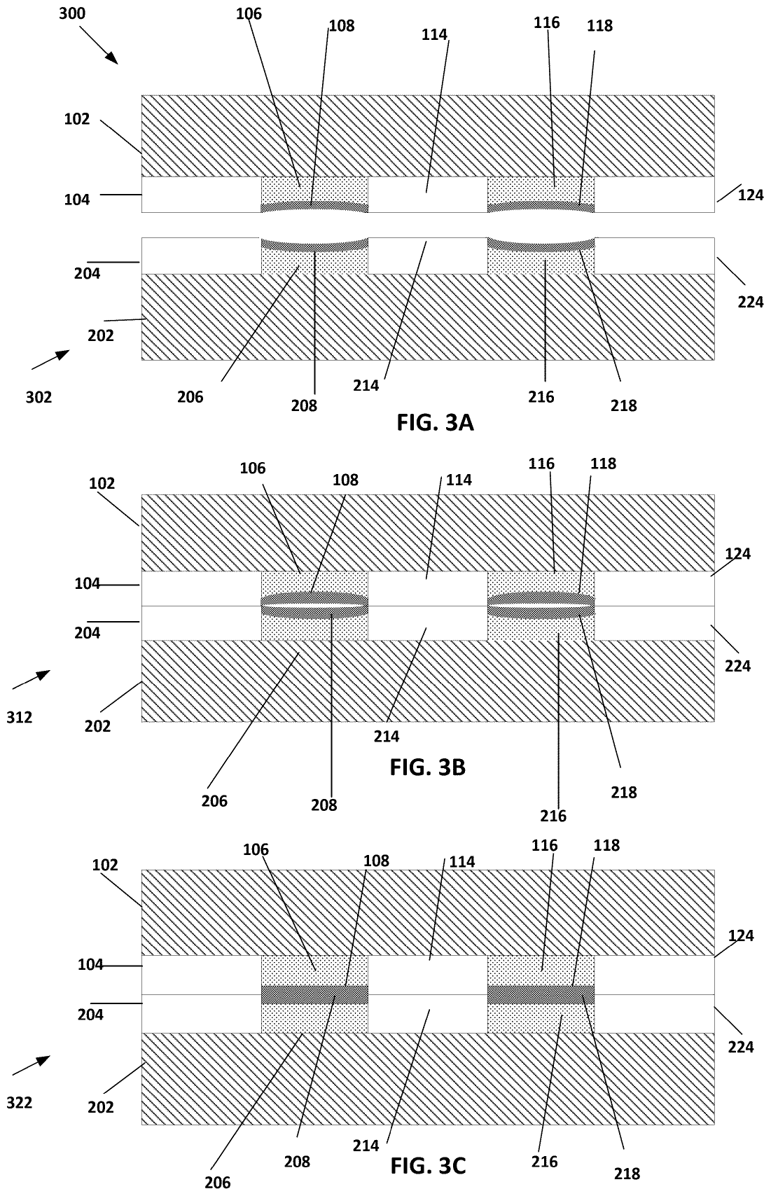

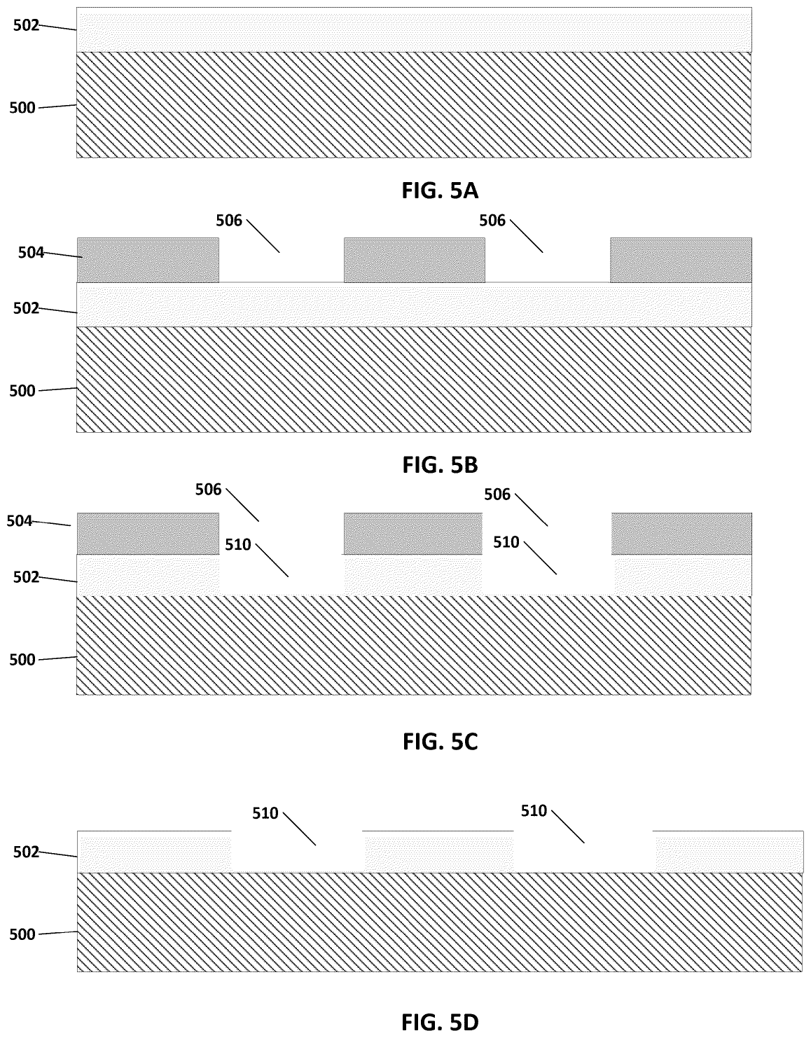

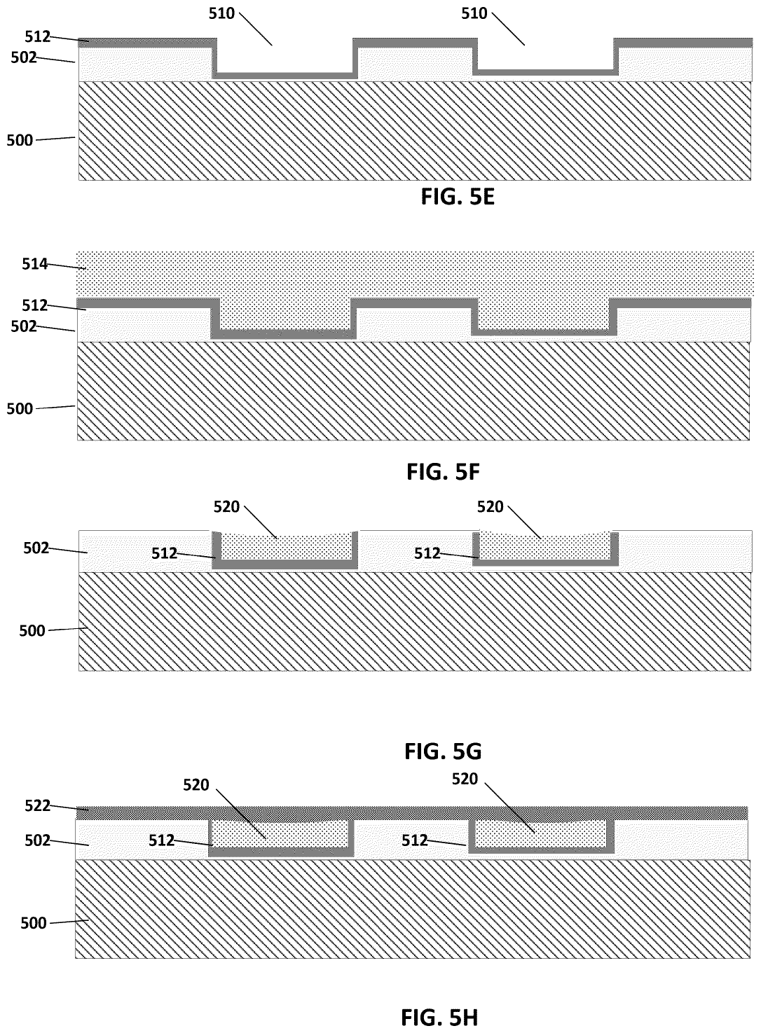

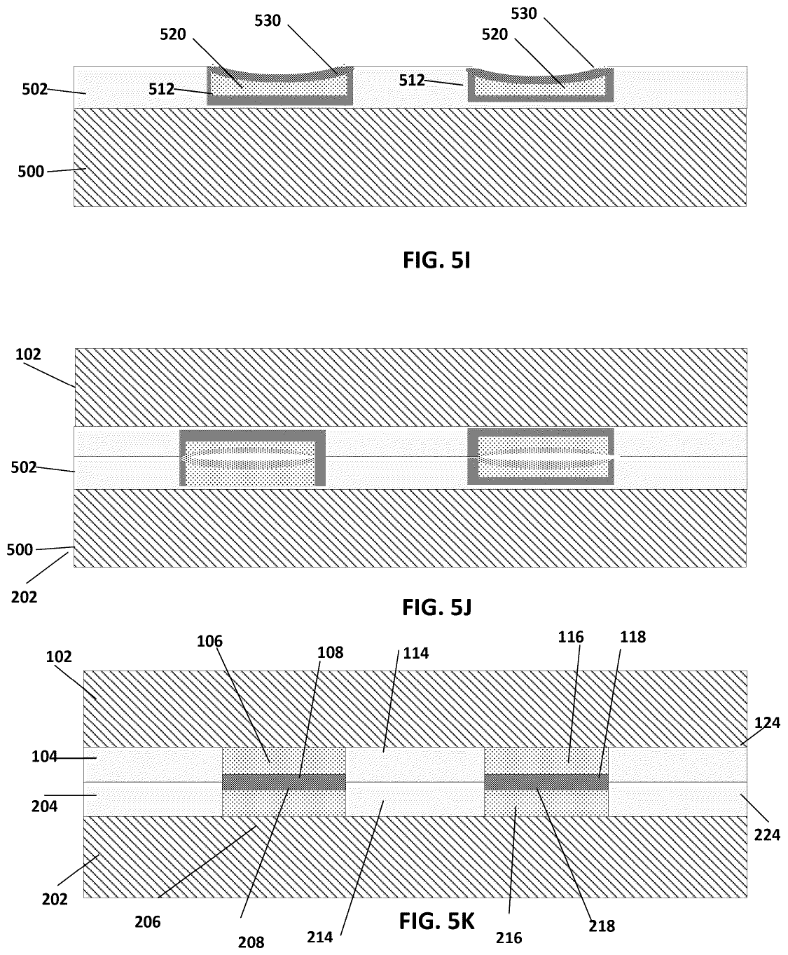

FIGS. 3A-3C provide an example embodiment of a first bonding 300 between the first substrate 102 and the second substrate 202. FIG. 3A. shows a pre-bonding position 302 where the substrates are spaced apart so that none of the surface layers of either the first substrate 102 or the second substrate 202 are in contact with each other. In the example of FIG. 3A, the outer conductive layers of the first outer conductive portion 108, the second outer conductive portion 118, the third outer conductive portion 208, and the fourth outer conductive portion 218 demonstrate a small dimple within the structure in the shape of a small concave surface. This may be formed, for example, in a polishing process as discussed below with respect to FIGS. 5A-5K.

In position 312, as shown by FIG. 3B, the first substrate 102 and the second substrate 202 are moved such that the dielectric layers may be in contact. Contact between dielectric layers may result in dielectric fusion bonding at room temperature between opposing dielectric portions. As such at position 312, the first dielectric portion 104 may be bonded to the fourth dielectric portion 204, the second dielectric portion 114 may be bonded to the fifth dielectric portion 214, the third dielectric portion 124 may be bonded to the sixth dielectric portion 224. However, the opposing outer conductive layers of the first outer conductive portion 108 and the second outer conductive portion 118 to the third outer conductive portion 208, and the fourth outer conductive portion 218 are not yet bonded, with the previously mentioned dishing in the outer conductive layers preventing contact.

Between the position 312 and the position 322 shown in FIG. 3C, the packaging structure may be subject to an annealing process to bond the opposing outer conductive layers of the first outer conductive portion 108 and the second outer conductive portion 118 to the third outer conductive portion 208, and the fourth outer conductive portion 218. As a result of the small grain size in the outer conductive layers, the length of the grain boundaries (observed on the surface prior bonding) may be enhanced, acting as efficient mass transfer channels across the interface, and hence the grains may be able to grow across an initial bonding interface. In some embodiments, the reduction of the grain boundary area can reduce the Gibbs free energy of the grain structure, and may drive subsequent microstructure evolution (grain growth) during thermal annealing. Furthermore, differences between the base conductive layer and outer conductive layer may compensate for a mismatch in the Coefficient of Thermal Expansion (CTE).

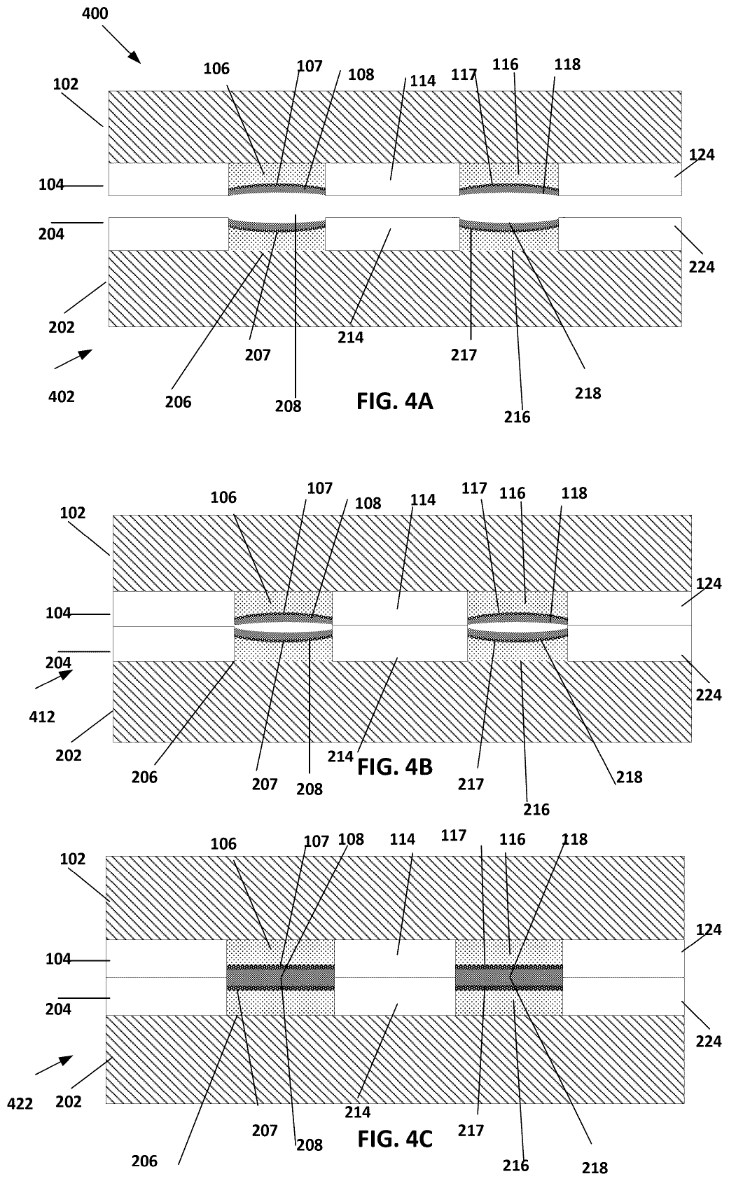

FIGS. 4A-4C demonstrate an example embodiment of a second bonding 400 between the first substrate 102 and the second substrate 202 when an intermediate conductive layer is included between the outer conductive layers and the base conductive layers. At position 402, the elements may be otherwise the same as pre-bonding position 302, with the addition of the first intermediate conductive portion 107 between the first base conductive portion 106 and the first outer conductive portion 108, the second intermediate conductive portion 117 between the second base conductive portion 116 and the second outer conductive portion 118, the third intermediate conductive portion 207 between the third base conductive portion 206 and the third outer conductive portion 208, and the fourth intermediate conductive portion 217 between the fourth base conductive portion 216 and fourth outer conductive portion 218. The first intermediate conductive portion 107, the second intermediate conductive portion 117, the third intermediate conductive portion 207, and the fourth intermediate conductive portion 217 thus experience the dimple in the inner and outer conductive layers, at positions 402 and 412. At position 422, after an annealing process, the intermediate conductive layers remain between the inner and outer conductive layers.

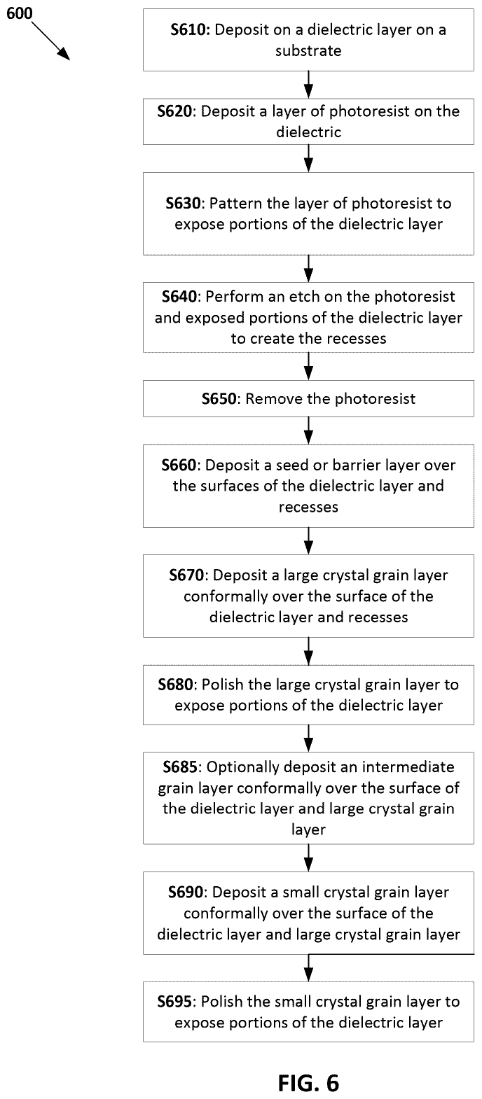

FIGS. 5A-5K provide an illustrative embodiment of the packaging process. FIG. 6 shows an example embodiment of a process 600 for forming a package structure corresponding to the illustrative embodiment of FIGS. 5A-5K.

FIG. 5A shows at S610 in FIG. 6 where a dielectric layer 502 is deposited onto a substrate 500. The dielectric layer 502 may be deposited directly on the substrate 500, or may have an intervening structure the dielectric layer 502 is deposited on. In some embodiments, the dielectric layer 502 may be instead grown on the substrate 500, for example via a diffusion process to obtain a layer of silicon oxide on a silicon substrate. In some embodiments, a combination of materials and techniques may be used to form multiple dielectric layers on the substrate 500.

FIG. 5B shows at S620 and S630 in FIG. 6 where a photoresist layer 504 is deposited onto the dielectric layer 502 and then patterned. The photoresist layer 504 is patterned to form a series of patterned recesses 506 exposing the surface of the dielectric layer 502.

FIG. 5C shows at S640 in FIG. 6 an etch process performed on the exposed surface of the dielectric layer 502 using the patterned recesses 506 in the photoresist layer. The dielectric layer is removed, for example using a chemical wet etch, a dry etch such as using plasma, or another process such as using laser exposure to form a recess 510 in the dielectric layer 502. The recess 510 may have a width of 50 nm to 5 μm, depending on the desired pitch and bonding process. For a W2W bond, the pitch may range from 100 nm to 1 μm, so the width of an interconnect might range from 50 nm to 500 μm. For D2W bonding, the pitch may range from 1 μm to 10 μm, so the width of an interconnect might be up to 5 μm. In addition, the recess 510 may, in some embodiments, have a depth equal to the thickness of the dielectric layer 502. However, in some embodiments, the recess 510 may have a depth only partially that of the dielectric layer 502, and in other embodiments, the recess 510 may have a depth greater than the dielectric layer 502 and penetrate into the substrate 500.

FIG. 5D demonstrates at S650 in FIG. 6 the removal of the remaining portions of the photoresist layer 504 from the dielectric layer 502. Such removal may be performed chemically, physically, or thermally. Portions of the dielectric layer 502 remaining between the recesses 510 may be referred to as unpatterned regions in addition to the dielectric layer 502.

FIG. 5E demonstrates at S660 in FIG. 6 the deposition of a seed layer 512 conformally over the surface of the dielectric layer 502 and the recess 510. The seed layer 512 may be deposited using a variety of processes, such as chemical vapor deposition, physical vapor deposition, or atomic layer deposition. Seed layer 512 may, in some embodiments, provide an interface to allow a larger grain base conductive layer 514 to bond to the substrate 500 or the dielectric layer 502. In some embodiments, the seed layer 512 may be used to impart a specific orientation onto the larger grain base conductive layer. In some embodiments, the seed layer 512 may be optional, with the larger grain base conductive layer 514 directly bonding to the substrate 500 or the dielectric layer 502.

FIG. 5F demonstrates at S670 in FIG. 6 the deposition of the larger grain base conductive layer 514 onto the seed layer 512. The deposition may be conformal and thus fill the recess 510 with the material of the larger grain base conductive layer 514. The deposition may be performed by a process such as an ECD plating process which may produce grains of about 0.5 to 5 microns in average grain size. The thickness of the larger grain base conductive layer 514 is sufficient to fully cover the recess 510 and the surface of the seed layer 512 on the dielectric layer 502. Alternatively, in some embodiments without the seed layer 512, the larger grain base conductive layer 514 may directly cover the dielectric layer 502.

FIG. 5G demonstrates at S680 in FIG. 6 polishing the surface of the substrate 500 after the deposition of the larger grain base conductive layer 514. A polishing process such as a chemical mechanical polish (CMP) removes excess portions of the larger grain base conductive layer 514 as well as any portions of the seed layer 512 outside of the recess 510. The remaining portions of the larger grain base conductive layer 514 form the large grain portions 520. Portions of the surface of the dielectric layer 502 may thus be exposed after removing portions of the seed layer 512 and the larger grain base conductive layer 514 outside of recess 510.

FIG. 5H shows at S690 in FIG. 6 depositing a smaller grain outer conductive layer 522 on the exposed surfaces of the substrate 500. The smaller grain outer conductive layer 522 may be deposited using PVD or ALD. The average grain size of the smaller grain outer conductive layer 522 may be 2-5 nm using ALD processes, and 5-10 nm using PVD processes. The thickness of the smaller grain outer conductive layer 522 may be comparable to the grain size, 2-10 nm or thicker. In some embodiments, the smaller grain outer conductive layer 522 may be a single monolayer of thickness.

FIG. 5I shows at S695 in FIG. 6 an additional polishing step to remove those portions of the smaller grain outer conductive layer 522 over the dielectric layer 502. In some embodiments, only a portion of the smaller grain outer conductive layer 522 (i.e., remaining portion 530) remains in the recess 510 in contact with the large grain portions 520. The remaining portion 530 may demonstrate a dimple where a CMP process previously removed excessive portions of the larger grain base conductive layer 514. The polishing step may also be a CMP process and compatible with high volume manufacturing. In some embodiments, a single polishing process may be used to remove portions of both the larger grain base conductive layer 514 and the smaller grain outer conductive layer 522. In some embodiments, a single lithography process may be used to define the recesses in both the larger grain base conductive layer 514 and the smaller grain outer conductive layer 522, while in some embodiments, multiple lithography steps may be used. In some embodiments, the lithography may be photolithography.

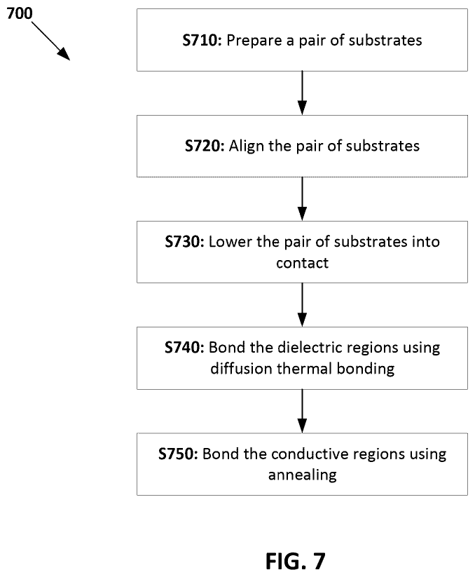

FIG. 7 describes a process 700 for bonding two substrates to form package. A second substrate 202 is added to the processing at S710 in FIG. 7, as the first substrate 102 and the second substrate 202 are prepared for joining after the polishing shown in FIG. 5I. The first substrate 102 and the second substrate 202 are aligned at S720 of FIG. 7 to so that the corresponding dielectric and conductive portions will contact when the substrates are lowed into place at S730, allowing the dielectric regions to bond using diffusion bonding at S740. FIG. 5J shows the result of the fusion bonding between dielectric regions and may be otherwise consistent with FIG. 3B. At S750 of FIG. 7, the conductive regions of the first substrate 102 and the second substrate 202 are bonded using an anneal process with the result shown in FIG. 5K. The results of S750 of FIG. 7 are consistent with FIG. 1 and FIG. 3C, demonstrating a completed packaging structure 100 after an annealing process causes the smaller grain outer conductive layer 522 of each substrate to join with an opposing structure. In some embodiments, the smaller grain outer conductive layer 522 of the first substrate 102 and the second substrate 202 may effectively merge into a single crystalline layer. The annealing process at S750 of FIG. 7 used to bond the smaller grain outer conductive layer 522 may be performed at a lower temperature than an equivalent anneal for the larger grain base conductive layer 514. For example, the smaller grain outer conductive layer 522 may bond at an anneal temperature of 50-100° C. less than the larger grain base conductive layer 514. For example, when the conductive layers are made of copper, the larger grain base conductive layer 514 may anneal at a temperature of 350° C. In comparison, the smaller grain outer conductive layer 522 may anneal at a temperature of 300° C. or less, 250° C. or less, or 150° C. or less. Furthermore, at these temperatures, the conductive layers may experience structural changes to the grain and may diffuse into surrounding substrate or dielectric materials.

While the example embodiments of FIG. 1, etc. show the first substrate 102 and the second substrate 202 as being the same, in other embodiments, the first substrate 102 and the second substrate 202 may be different from one another. For example, the number of dielectric layers, conductive layers, and the materials used in one substrate may be different from the number of dielectric layers, conductive layers, and the materials used in the other substrate. For example, the smaller grain outer conductive layer 522 in each substrate may differ in composition as well as orientation. Furthermore, the orientation of the base conductive layers may differ from the outer conductive layers and the intermediate conductive layers. As disclosed herein, the orientation of each conductive layer may be random. As used herein, orientation may refer to the grain orientation or crystalline orientation, for example, a silicon wafer may have crystalline orientations including 100, 111, 110, 112, 211, and 511 based on the direction of crystals oriented within the lattice forming the wafer. In some embodiments, layers may be formed having the same orientation as an underlying layer, while in some embodiments, layers may be formed having orientations different from the underlying layers.

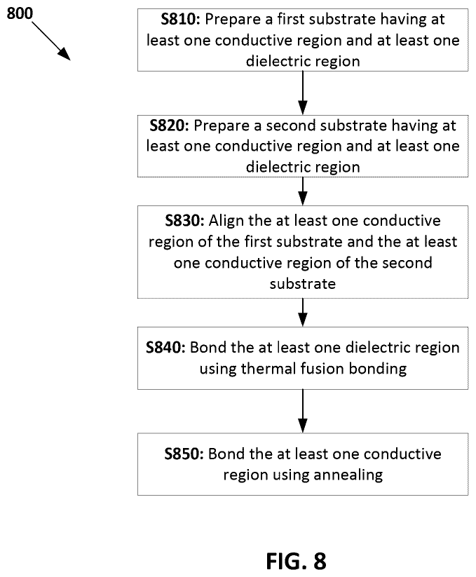

FIG. 8 demonstrates a high-level view of a process 800 for forming a packaged device. At S810 a first substrate is prepared having at least one conductive region and one dielectric region, for example, according to the process 600 in FIG. 6. At S820, a second substrate is prepared having at least one conductive region and one dielectric region, for example, for example, according to the process 600 in FIG. 6. At S830, the first substrate and the second substrate are aligned, for example, with the at least one conductive region and one dielectric region of the first substrate opposite the at least one conductive region and one dielectric region of the second substrate. At S840, the first substrate and the second substrate are joined together, for example by lowering one substrate onto each other, such that the at least one dielectric region of each substrate are in contact. At room temperature, a fusion bonding process will take place between two dielectric regions in contact. At S850, the substrates are then subjected to an annealing process to bond the at least one conductive region of the first substrate to the at least one conductive region of the second substrate.

In some embodiments, the bonding temperature required to anneal copper surfaces together may correspond to the roughness of each of the copper surfaces. In some embodiments, a larger grain copper layer may be deposited via an ECD process, and smaller grain copper layer may be deposited via a PVD process. The smaller grain size copper layer formed by PVD may enhance the length of the grain boundaries compared to those on the surface prior to bonding, acting as an efficient mass transfer channels across the interface, and hence the grains may be able to grow over an initial bonding interface. In some embodiments, the reduction of the grain boundary area can be a major driving force to reduce the Gibbs free energy of the structure and may drive subsequent microstructure evolution (grain growth) during thermal annealing. In some embodiments, decreasing surface roughness of Cu can also lower the thermal budget in Cu-to-Cu bonding, as the anneal temperature may drop corresponding to the lower surface roughness.

As such, the packaging process disclosed herein may, in some embodiments, allow for low temperature Cu—Cu bonding, enabling the use of a wide range of types of substrates, such as organic substrates. The bonding may also be independent of the orientation of the grains, with the thin interface between the smaller grain conductive layers allowing the smaller grain layers to intermix during annealing to form a single monolayer.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

As will be recognized by those skilled in the art, the innovative concepts described herein may be modified and varied over a wide range of applications. Accordingly, the scope of claimed subject matter should not be limited to any of the specific exemplary teachings discussed above, but is instead defined by the following claims.

What is claimed is:

1. A device comprising:
a first substrate comprising a first conductive region and a first insulative region;
a second substrate comprising a second conductive region contacting the first conductive region, and a second insulative region contacting the first insulative region;
the first conductive region having a first grain layer and a second grain layer contacting the first grain layer, the second grain layer having a larger average grain size than the first grain layer;
the second conductive region having a third grain layer and a fourth grain layer contacting the third grain layer, the fourth grain layer having a larger average grain size than the third grain layer; and
wherein at least one of the first grain layer and the third grain layer has a thickness of a single-grain layer.

2. The device of claim 1, wherein a crystalline orientation of the first grain layer and the second grain layer differ; and wherein a crystalline orientation of the third grain layer and the fourth grain layer differ.

3. The device of claim 1, wherein a crystalline orientation of the first grain layer and the second grain layer are substantially the same; and wherein a crystalline orientation of the third grain layer and the fourth grain layer are substantially the same.

4. The device of claim 1, wherein a crystalline orientation of the first grain layer and the third grain layer are substantially the same; and wherein a crystalline orientation of the second grain layer and the fourth grain layer differ.

5. The device of claim 1, wherein the first grain layer and the third grain layer have substantially the same average grain size.

6. The device of claim 1, wherein the first grain layer comprises a first copper layer and the second grain layer comprises a second copper layer different from the first copper layer; and
wherein the third grain layer comprises a third copper layer and the fourth grain layer comprises a fourth copper layer different from the third copper layer.

7. The device of claim 6, wherein the second copper layer differs from the fourth copper layer.

8. The device of claim 7, wherein at least one of the first grain layer and the third grain layer forms an electromigration barrier between the second grain layer and the fourth grain layer.

9. The device of claim 1, wherein the average grain size of at least one of the first grain layer and the third grain layer is less than about 10 nanometers; and wherein the average grain size of each of the second grain layer and the fourth grain layer is greater than about 0.1 micron.

10. A device comprising:
a first grain layer contacting a first substrate;
a second grain layer contacting a second substrate; and
a third grain layer contacting the first grain layer and the second grain layer, the third grain layer having an average grain size smaller than the first grain layer and the second grain layer.

11. The device of claim 10, wherein a crystalline orientation of the first grain layer, the second grain layer, and the third grain layer are substantially the same.

12. The device of claim 10, wherein a crystalline orientation of the first grain layer and the second grain layer differ; and
wherein a crystalline orientation of the third grain layer differs from both the first grain layer and the second grain layer.

13. The device of claim 10, wherein a crystalline orientation of the first grain layer and the second grain layer differ; and wherein a crystalline orientation of the third grain layer differs at least one of the first grain layer and the second grain layer.

14. A method comprising:
depositing a first insulative region on a first substrate, forming a first recess in the first insulative region, and depositing a first conductive layer in the first recess;
depositing a second insulative region on a second substrate, forming a second recess in the second insulative region, and depositing a second conductive layer in the second recess;
forming a third conductive layer on the first conductive layer and forming a fourth conductive layer on the second conductive layer, at least one of the third conductive layer and the fourth conductive layer having a different grain orientation than the first conductive layer and the second conductive layer;
bonding the first insulative region to the second insulative region; and
annealing the first substrate and the second substrate at temperature of less than 250° C. to bond the third conductive layer and the fourth conductive layer into a single layer.

15. The method of claim 14, wherein the first conductive layer and the second conductive layer are formed using electro-chemical deposition plating; and wherein the third conductive layer and the fourth conductive layer are formed using at least one of physical layer deposition and atomic layer deposition.

16. The method of claim 14, further comprising annealing the first substrate and the second substrate at temperature of less than 200° C.

17. The method of claim 14, further comprising annealing the first substrate and the second substrate at temperature between 150° C. and 250° C.

18. The method of claim 14, further comprising:
polishing the first conductive layer to expose a surface of the first insulative region prior to forming the third conductive layer;
polishing the second conductive layer to expose a surface of the second insulative region prior to forming the fourth conductive layer; and
polishing the third conductive layer to expose the surface of the first insulative region and polishing the fourth conductive layer to expose the surface of the second insulative region prior to bonding the first insulative region to the second insulative region.

19. The method of claim 14, further comprising:
polishing the first conductive layer and the third conductive layer together to expose a surface of the first insulative region; and
polishing the second conductive layer and the fourth conductive layer together to expose a surface of the second insulative region.

20. The method of claim 14, wherein forming the first recess in the first insulative region and forming the second recess in the second insulative region are done using photolithography; and wherein the third conductive layer and the fourth conductive layer are unpatterned when bonded.
